(19) United States
(12) Patent Application Publication
(10) Pub. No.: US 2026/0280511 A1
(43) Pub. Date: Sep. 17, 2026

(54) ACOUSTIC WAVE DEVICE

(71) Applicant: Murata Manufacturing Co., Ltd., Nagaokakyo-shi (JP)

(72) Inventor: Hideaki TAKAHASHI, Nagaokakyo-shi (JP)

(21) Appl. No.: 19/668,106

(22) Filed: May 5, 2026

Related U.S. Application Data
(63) Continuation of application No. PCT/JP2024/043207, filed on Dec. 6, 2024.

(30) Foreign Application Priority Data
Dec. 13, 2023 (JP) 2023-210251

(51) Int. Cl. H03H 9/02; H03H 9/05; H03H 9/13; H03H 9/17

(52) U.S. Cl. CPC H03H 9/02228; H03H 9/02031; H03H 9/02157; H03H 9/0523; H03H 9/132; H03H 9/173; H03H 9/176

(57) ABSTRACT

An acoustic wave device includes a support substrate, an intermediate layer on the support substrate, a piezoelectric layer on the intermediate layer, and an IDT electrode on the piezoelectric layer and including a plurality of electrode fingers. When a thickness of a portion of the piezoelectric layer in which the IDT electrode is provided is d, and a distance between centers of adjacent electrode fingers is p, d/p is about 0.5 or smaller. A cavity is between the piezoelectric layer and the support substrate, and overlaps with the IDT electrode in plan view. The acoustic wave device further includes one of a silicon nitride film, an amorphous silicon film, or a polycrystalline silicon film each including at least a portion provided between the support substrate and the intermediate layer and each facing the piezoelectric layer with at least one of the cavity and the intermediate layer therebetween.

### CROSS REFERENCE TO RELATED APPLICATIONS

This application claims the benefit of priority to Japanese Patent Application No. 2023-210251 filed on Dec. 13, 2023 and is a Continuation Application of PCT Application No. PCT/JP2024/043207 filed on Dec. 6, 2024. The entire contents of each application are hereby incorporated herein by reference.

### BACKGROUND OF THE INVENTION

### 1. Field of the Invention

The present invention relates to acoustic wave devices.

### 2. Description of the Related Art

Conventionally, an acoustic wave device is widely used in a filter of a mobile phone and the like. In recent years, an acoustic wave device that uses a bulk wave in a thickness shear mode as described in International Publication No. 2022/210809 has been proposed. In this acoustic wave device, an intermediate layer is provided on a support substrate. A piezoelectric layer is provided on the intermediate layer. A functional electrode is provided on the piezoelectric layer. The functional electrode includes a plurality of pairs of electrode fingers. The pair of electrode fingers faces each other on the piezoelectric layer and is connected to different electric potentials. A bulk wave in the thickness shear mode is excited by an AC voltage being applied between the electrode fingers.

A recessed portion is provided in the intermediate layer. The piezoelectric layer covers the recessed portion. As a result, a space portion is provided between the piezoelectric layer and the support substrate. The space section is located in a portion that overlaps with the functional electrode in plan view.

### SUMMARY OF THE INVENTION

In International Publication No. 2022/210809, silicon oxide is used as an example of the material of the intermediate layer. Si is used as an example of the material of the support substrate. When the support substrate and the intermediate layer that are made of materials as described above are laminated together, a low-resistance layer may be formed due to the electric charge contained in the intermediate layer or the electric charge captured in the interface state at the interface of the support substrate.

However, in the acoustic wave device in International Publication No. 2022/210809, a cavity is provided between the support substrate and a portion of the piezoelectric layer in which the functional electrode is formed. That is, the cavity is provided between the support substrate and the portion in which a bulk wave in the thickness shear mode is generated. Accordingly, even when a low-resistance layer is formed, the effect of the acoustic wave device on the electrical characteristics is considered to be suppressed. Concerning this, the present inventor has found that the electrical characteristics of the acoustic wave device may be degraded due to the formation of a low-resistance layer even when the cavity is provided.

Example embodiments of the present invention provide acoustic wave devices that each prevent electrical characteristics from being degraded.

According to an example embodiment of the present invention, an acoustic wave device includes a support substrate, an intermediate layer on the support substrate, a piezoelectric layer on the intermediate layer; and an IDT electrode on the piezoelectric layer and including a plurality of electrode fingers, in which d/p is about 0.5 or smaller where a thickness of a portion of the piezoelectric layer in which the IDT electrode is provided is d, and a distance between centers of adjacent electrode fingers of the plurality of electrode fingers is p, a cavity is between the piezoelectric layer and the support substrate and overlaps with the IDT electrode in plan view, the acoustic wave device further including one of a silicon nitride film, an amorphous silicon film, or a polycrystalline silicon film each including at least a portion provided between the support substrate and the intermediate layer and each facing the piezoelectric layer with at least one of the cavity and the intermediate layer therebetween.

In acoustic wave devices according to example embodiments of the present invention, the electrical characteristics are prevented from being degraded.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a simplified front cross-sectional view of an acoustic wave device according to a first example embodiment of the present invention.

FIG. 2 is a schematic plan view of an acoustic wave resonator in the first example embodiment of the present invention.

FIG. 3 is a schematic front cross-sectional view of an acoustic wave device according to a modification of the first example embodiment of the present invention.

FIG. 4 is a schematic front cross-sectional view of an acoustic wave device according to a first comparative example.

FIG. 5 is a diagram illustrating the phase characteristics in the first comparative example.

FIG. 6 is a diagram illustrating the phase characteristics in the modification of the first example embodiment of the present invention.

FIG. 7 is a simplified front cross-sectional view of an acoustic wave device according to a second example embodiment of the present invention.

FIG. 8 is a diagram illustrating the relationship between d/p and the fractional bandwidth of the acoustic wave resonator.

FIG. 9 is a diagram illustrating the relationship between the fractional bandwidth of the acoustic wave resonator and the normalized magnitude of spurious emission.

FIG. 10 is a diagram illustrating the relationship between d/p, a metallization ratio MR, and the fractional bandwidth.

FIG. 11 is a diagram illustrating the map of the fractional bandwidth with respect to the Euler angles (0°, θ, ψ) of LiNbO₃ when d/p approaches 0 without limit.

### DETAILED DESCRIPTION OF THE EXAMPLE EMBODIMENTS

The present invention will be clarified by specific example embodiments of the present invention being described with reference to the drawings.

It should be noted that example embodiments described in this specification are exemplary and that partial substitutions or combinations of structures between different example embodiments are possible.

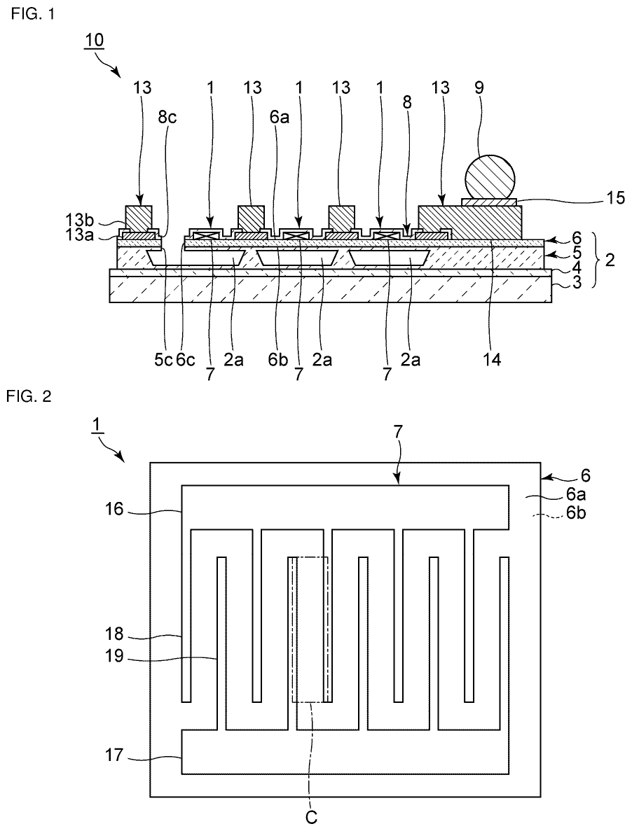

FIG. 1 is a simplified front cross-sectional view of an acoustic wave device according to a first example embodiment of the present invention. FIG. 1 illustrates IDT (interdigital transducer) electrodes, which will be described later, by using a simplified view including rectangles each having two diagonal lines. This is also true in the simplified front cross-sectional views other than FIG. 1.

An acoustic wave device 10 according to the present example embodiment is a filter device that includes a plurality of resonators. Specifically, the plurality of resonators of the acoustic wave device 10 are each an acoustic wave resonator 1. However, the present invention is not limited to this example. The plurality of resonators of the acoustic wave device 10 may include at least one acoustic wave resonator 1.

It should be noted that an acoustic wave device according to an example embodiment of the present invention may be an element that includes a plurality of resonators, such as acoustic wave resonators, and may be used as a portion of a filter device. Alternatively, an acoustic wave device according to an example embodiment of the present invention may include only one acoustic wave resonator.

The specific structure of the acoustic wave device 10 will be described below. As illustrated in FIG. 1, the acoustic wave device 10 includes a piezoelectric substrate 2 and a plurality of IDT electrodes 7. The piezoelectric substrate 2 is a substrate having piezoelectricity. Specifically, the piezoelectric substrate 2 includes the support substrate 3, a silicon nitride film 4, an intermediate layer 5, and a piezoelectric layer 6. The silicon nitride film 4 is provided on the support substrate 3. The intermediate layer 5 is provided on the silicon nitride film 4. The piezoelectric layer 6 is provided on the intermediate layer 5.

In the present example embodiment, the support substrate 3 is a silicon substrate. It should be noted that the material of the support substrate 3 is not limited to silicon and may also be, for example, quartz or glass. In the present example embodiment, the intermediate layer 5 is a silicon oxide layer. It should be noted that the material of the intermediate layer 5 is not limited to silicon oxide and may also be, for example, tantalum oxide. The piezoelectric layer 6 is made of, for example, lithium niobate, such as LiNbO₃, or lithium tantalate, such as LiTaO₃. In this specification, when it is stated that a certain component is made of a certain material, the certain component may include a slight amount of impurity to the extent that the electrical characteristics of the acoustic wave device are not significantly degraded.

A plurality of cavities 2a are provided in the intermediate layer 5. Specifically, each of the cavities 2a is a hollow portion provided in the intermediate layer 5. In a portion in which the cavity 2a is provided, the silicon nitride film 4 and the piezoelectric layer 6 face each other with both the intermediate layer 5 and the cavity 2a located therebetween. However, the cavity 2a may be formed by, for example, a recessed portion provided in the intermediate layer 5 being blocked by one of the piezoelectric layer 6 and the silicon nitride film 4. Alternatively, the cavity 2a may also be a through-hole provided in the intermediate layer 5 being blocked by both the piezoelectric layer 6 and the silicon nitride film 4. It should be noted that a portion of the cavity 2a may be connected to the outside through a through-hole or the like.

As illustrated in FIG. 1, in a portion in which the cavity 2a is provided, the silicon nitride film 4 and the piezoelectric layer 6 face each other with both the intermediate layer 5 and the cavity 2a therebetween. On the other hand, in a portion in which the cavity 2a is not provided, the silicon nitride film 4 and the piezoelectric layer 6 face each other with the intermediate layer 5 therebetween. As described above, in the present example embodiment, the silicon nitride film 4 and the piezoelectric layer 6 face each other with at least the intermediate layer 5 therebetween.

However, as described above, the cavity 2a may also be the through-hole provided in the intermediate layer 5 being blocked by both the piezoelectric layer 6 and the silicon nitride film 4. In this case, in the portion in which the cavity 2a is provided, the silicon nitride film 4 and the piezoelectric layer 6 face each other with the cavity 2a provided and the intermediate layer 5 not provided therebetween. In an example embodiment of the present invention, the silicon nitride film 4 and the piezoelectric layer 6 only need to face each other with at least one of the cavity 2a and the intermediate layer 5 located therebetween.

It should be noted that, in an example embodiment of the present invention, the film corresponding to the silicon nitride film 4 may be an amorphous silicon film or a polycrystalline silicon film.

The piezoelectric layer 6 includes a first main surface 6a and a second main surface 6b. The first main surface 6a and the second main surface 6b face away from each other. Of the first main surface 6a and the second main surface 6b, the second main surface 6b is located close to the support substrate 3.

The plurality of IDT electrodes 7 are provided on the first main surface 6a of the piezoelectric layer 6. The plurality of IDT electrodes 7 overlap with the cavities 2a of the piezoelectric substrate 2, respectively, in plan view. In this specification, plan view refers to view from the up side in FIG. 1 along the lamination direction of the individual layers of the piezoelectric substrate 2, such as the support substrate 3 and the piezoelectric layer 6. It should be noted that, in FIG. 1, for example, of the side close to the support substrate 3 and the side close to the piezoelectric layer 6, the side close to the piezoelectric layer 6 corresponds to the up side. In addition, in this specification, plan view is the same as view in a main surface facing direction. The main surfaces facing direction is the direction in which the first main surface 6a and the second main surface 6b of the piezoelectric layer 6 face away from each other. More specifically, the main surface facing direction is, for example, the normal direction of the first main surface 6a.

The IDT electrodes 7 overlap with different cavities 2a, respectively, in plan view. It should be noted that the plurality of IDT electrodes 7 may overlap with the same cavity 2a in plan view.

The acoustic wave resonators 1 each include the piezoelectric substrate 2 and the IDT electrode 7. The specific structure of the IDT electrode 7 will be described below.

FIG. 2 is a schematic plan view of the acoustic wave resonator in the first example embodiment. It should be noted that a dielectric film and wiring lines, which will be described later, are not illustrated in FIG. 2.

The IDT electrode 7 includes a pair of busbars and a plurality of electrode fingers. The pair of busbars is specifically a first busbar 16 and a second busbar 17. The first busbar 16 and the second busbar 17 face each other. The plurality of electrode fingers are specifically a plurality of first electrode fingers 18 and a plurality of second electrode fingers 19. One ends of the plurality of first electrode fingers 18 are connected to the first busbar 16. One ends of the plurality of second electrode fingers 19 are connected to the second busbar 17. The plurality of first electrode fingers 18 and the plurality of second electrode fingers 19 are interdigitated with each other. The electric potential to which the first electrode fingers 18 are connected and the electric potential to which the second electrode fingers 19 are connected differ from each other. The IDT electrode 7 may be a single-layer metal film or a multilayer metal film.

The first electrode fingers 18 and the second electrode fingers 19 may be collectively referred to below simply as the electrode fingers. The direction in which the plurality of electrode fingers extend is referred to as an electrode finger extension direction, and the direction orthogonal to the electrode finger extension direction is referred to as an electrode finger orthogonal direction.

The acoustic wave resonator 1 is configured so as to be able to use a bulk wave in the thickness shear mode. More specifically, the region, between the centers of adjacent electrode fingers, in which the adjacent electrode fingers overlap with each other as viewed in the electrode finger orthogonal direction is an excitation region C. The acoustic wave resonator 1 includes the plurality of excitation regions C. In FIG. 2, one of the plurality of excitation regions C is indicated by a dot-dash line. A bulk wave in the thickness shear mode is excited in each of the excitation regions C by an AC voltage being applied to the IDT electrode 7. It should be noted that the excitation regions C are regions in the piezoelectric layer 6 that are defined in accordance with the structure of the IDT electrode 7.

When the thickness of a portion of the piezoelectric layer 6 in which the IDT electrode 7 is provided is d, and the distance between the centers of adjacent electrode fingers is p, d/p is about 0.5 or smaller, for example. As a result, a bulk wave in the thickness shear mode is suitably excited. The acoustic wave resonators 1 illustrated in FIG. 1 are configured so as to be able to use a bulk wave in the thickness shear mode. It should be noted that the design parameters and the thickness d concerning the IDT electrode 7 may differ from each other between the plurality of acoustic wave resonators 1 according to desired characteristics.

A plurality of wiring lines 13 are provided on the first main surface 6a of the piezoelectric layer 6. The plurality of IDT electrodes 7 are electrically connected to each other by the wiring lines 13. The plurality of wiring lines 13 may each include a multilayer metal film. Specifically, the plurality of wiring lines 13 each include a first wiring layer 13a and a second wiring layer 13b. The first wiring layer 13a is provided on the first main surface 6a of the piezoelectric layer 6. The second wiring layer 13b is provided on the first wiring layer 13a. It should be noted that the number of layers of the plurality of wiring lines 13 is not limited to two. The plurality of wiring lines 13 may each include a metal film with three or more layers or a single-layer metal film.

At least one wiring line 13 includes a pad portion 14. In the present example embodiment, the pad portion 14 is directly provided on the first main surface 6a of the piezoelectric layer 6. The pad portion 14 includes the second wiring layer 13b. It should be noted that the pad portion 14 may include a multilayer metal film including the first wiring layer 13a and the second wiring layer 13b.

A pad electrode 15 is provided on the pad portion 14. A bump 9 is provided on the pad electrode 15. The bump 9 is made of Au. However, the material of the bump 9 is not limited to Au. Alternatively, a conductive adhesive or the like may be provided instead of the bump 9.

It should be noted that, in a portion not illustrated, at least one pad portion 14, at least one pad electrode 15, and at least one bump 9 are provided. The acoustic wave device 10 is electrically connected to the outside via the wiring lines 13, the pad electrodes 15, and the bumps 9.

A dielectric film 8 is provided on the first main surface 6a of the piezoelectric layer 6 so as to cover the plurality of IDT electrodes 7. As a result, the plurality of IDT electrodes 7 are protected. Accordingly, the plurality of IDT electrodes 7 are not easily damaged. In the present example embodiment, the dielectric film 8 covers portions of the first wiring layers 13a of the plurality of wiring lines 13. However, the dielectric film 8 need not be in contact with the first wiring layers 13a. The material of the dielectric film 8 may be, for example, silicon oxide, silicon nitride, or silicon oxynitride. It should be noted that the dielectric film 8 need not necessarily be provided.

As illustrated in FIG. 1, a through-hole is provided in a portion of the piezoelectric substrate 2 and the dielectric film 8 so as to reach the cavity 2a. Specifically, a through-hole 5c is provided in a portion of the intermediate layer 5 between the cavity 2a and the piezoelectric layer 6. A through-hole 6c is provided in the piezoelectric layer 6. A through-hole 8c is provided in the dielectric film 8. The through-hole including the through-holes 5c, 6c, and 8c communicating with each other reaches the cavity 2a. It should be noted that a through-hole is similarly provided in a portion of the acoustic wave device 10 that is not illustrated. These through-holes are provided to form the cavities 2a by etching when the acoustic wave device 10 is manufactured. However, these through-holes need not necessarily be provided.

An example embodiment of the present invention is characterized by the following structures. 1) The cavity 2a is provided between the piezoelectric layer 6 and the support substrate 3, and the cavity 2a overlaps with the IDT electrode 7 in plan view. 2) The silicon nitride film 4 is provided between the support substrate 3 and the intermediate layer 5 and faces the piezoelectric layer 6 with at least one of the cavity 2a and the intermediate layer 5 therebetween. It should be noted that an amorphous silicon film or a polycrystalline silicon film may be provided instead of the silicon nitride film 4. The structure described above can prevent the electrical characteristics of the acoustic wave device 10 from being degraded. Details of this will be described below by comparison between a modification of the first example embodiment and a first comparative example.

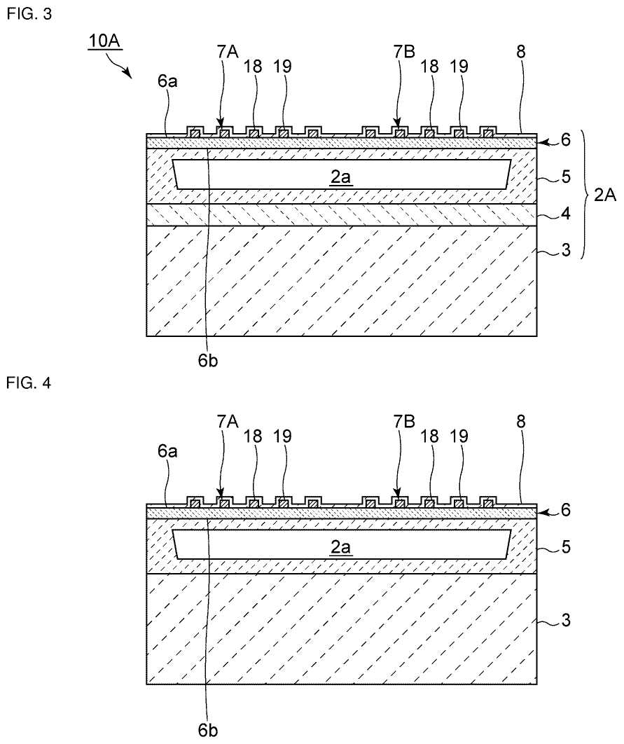

FIG. 3 is a schematic front cross-sectional view of an acoustic wave device according to the modification of the first example embodiment. FIG. 4 is a schematic front cross-sectional view of an acoustic wave device according to the first comparative example.

An acoustic wave device 10A according to the modification of the first example embodiment illustrated in FIG. 3 is a two-port acoustic wave resonator. In the acoustic wave device 10A, the multilayer structure of a piezoelectric substrate 2A is the same as that of the piezoelectric substrate 2 in the first example embodiment. An IDT electrode 7A and an IDT electrode 7B are provided on the first main surface 6a of the piezoelectric layer 6 in the piezoelectric substrate 2A. The IDT electrode 7A and the IDT electrode 7B overlap with a cavity 2a in plan view.

The first comparative example illustrated in FIG. 4 differs from the modification of the first example embodiment in that the silicon nitride film 4 is not provided. The phase characteristics were compared between the modification of the first example embodiment and the first comparative example.

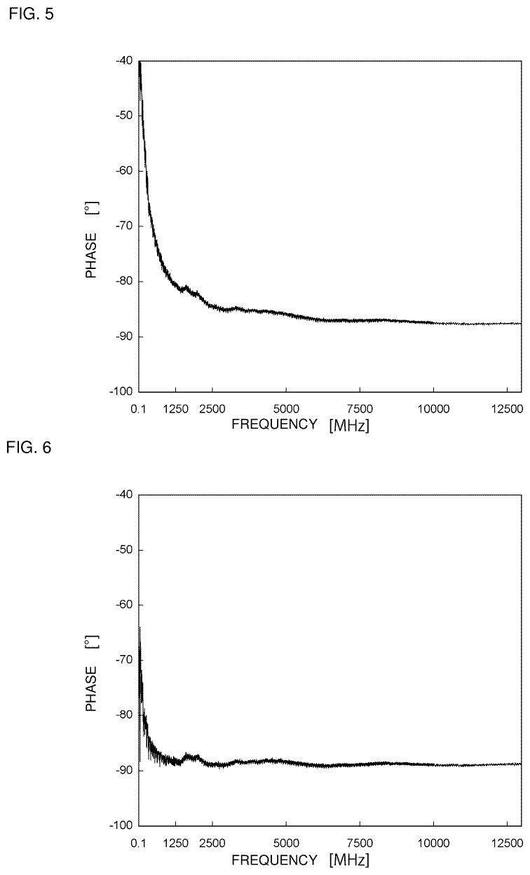

FIG. 5 is a diagram illustrating the phase characteristics in the first comparative example. FIG. 6 is a diagram illustrating the phase characteristics in the modification of the first example embodiment.

As illustrated in FIG. 5, it can be seen that the phase deviates significantly from −90° in the range of 1250 MHz or higher and 7500 MHz or lower in the first comparative example. In contrast, it can be seen that the phase is close to −90° in the range of 1250 MHz or higher and 7500 MHz or lower in the modification of the first example embodiment illustrated in FIG. 6. As described above, in the modification, the electrical characteristics are prevented from being degraded. Also in the acoustic wave resonators 1 in the first example embodiment illustrated in FIG. 1, the electrical characteristics can be prevented from being degraded as in the modification.

In the acoustic wave device according to the first comparative example illustrated in FIG. 4, the cavity 2a is provided in a portion that overlaps with the IDT electrode 7A and the IDT electrode 7B in plan view. In this case, the path of electron movement between the IDT electrodes 7A and 7B and the support substrate 3 is blocked by the cavity 2a. Accordingly, it can also be considered that, even if a low-resistance layer is formed when, for example, a bulk wave in the thickness shear mode is excited, the effect on the electrical characteristics is reduced or prevented.

In contrast, the present inventor has discovered that, when a low-resistance layer is formed, the electric charge accumulated in the cavity 2a moves through the intermediate layer 5, and accordingly, the electrical characteristics of the acoustic wave resonator may be degraded. That is, the present inventor has discovered that the degradation of the electrical characteristics of the first comparative example illustrated in FIG. 5 is caused by the movement of the electric charge described above. In the first example embodiment and the modification thereof illustrated in FIGS. 1 and 3, the silicon nitride film 4 is provided between the support substrate 3 and the intermediate layer 5. As a result, a low-resistance layer is prevented from being formed between the support substrate 3 and the intermediate layer 5. As a result, the electrical characteristics of the acoustic wave device can be prevented from being degraded.

In addition, in the acoustic wave resonators 1 illustrated in FIG. 1, the IDT electrode 7 and the cavity 2a overlap with each other in plan view, and accordingly, the energy of an acoustic wave can be effectively confined on the side close to the piezoelectric layer 6. Accordingly, in the acoustic wave resonators 1, the Q value can be effectively increased. Also in the modification of the first example embodiment, the Q value can also be effectively increased.

It should be noted that, even when an amorphous silicon film or a polycrystalline silicon film is provided instead of the silicon nitride film 4, a low-resistance layer can be prevented from being formed between the support substrate 3 and the intermediate layer 5. In an example embodiment of the present invention, it is sufficient for one of the silicon nitride film 4, the amorphous silicon film, and the polycrystalline silicon film to be provided between the support substrate 3 and the intermediate layer 5 and face the piezoelectric layer 6 with at least one of the cavity 2a and the intermediate layer 5 therebetween. As a result, the electrical characteristics can be prevented from being degraded, and the Q value can be effectively increased.

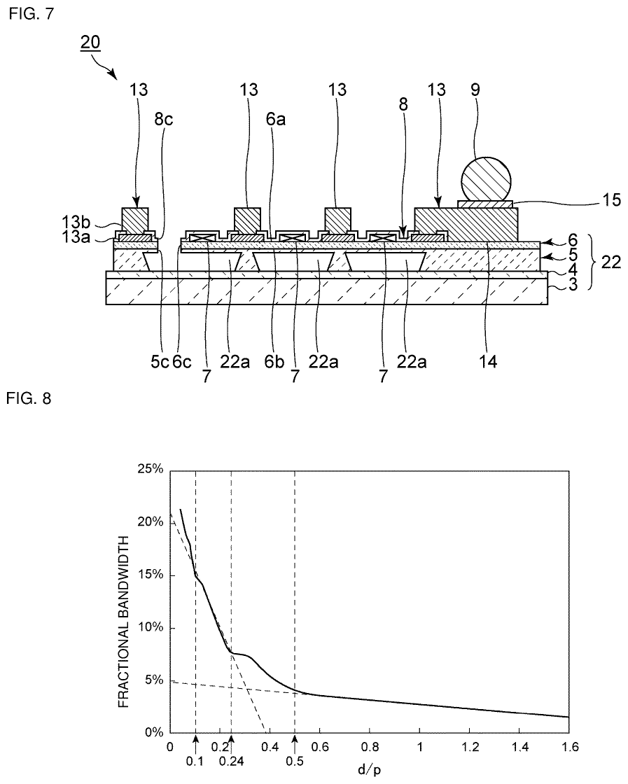

FIG. 7 is a simplified front cross-sectional view of an acoustic wave device according to a second example embodiment.

The second example embodiment differs from the first example embodiment in that the silicon nitride film 4 faces a cavity 22a in the piezoelectric substrate 22. In the second example embodiment, the cavity 22a is formed by the silicon nitride film 4 being provided so as to block the recessed portion provided in the intermediate layer 5. The acoustic wave device 20 according to the second example embodiment has the same structure as the acoustic wave device 10 according to the first example embodiment with the exception described above.

When a structure excluding the silicon nitride film 4 from the second example embodiment is assumed, the support substrate 3 and the intermediate layer 5 are not laminated in a portion that overlaps with the IDT electrode 7 in plan view. The present inventor has discovered that, even in such a case, the electric charge accumulated in the cavity 2a moves through a portion of the intermediate layer 5 that faces the cavity 2a, and accordingly, the electrical characteristics of the acoustic wave resonators may be degraded.

In contrast, in the second example embodiment, the silicon nitride film 4 is provided between the support substrate 3 and the intermediate layer 5 and faces the piezoelectric layer 6 with at least one of the cavity 2a and the intermediate layer 5 therebetween. As a result, also in the second example embodiment, the electrical characteristics of the acoustic wave device 20 can be prevented from being degraded, as in the first example embodiment. In addition, the Q value can be effectively increased.

A preferred structure of the present invention will be described with reference to FIG. 1. However, the preferred structure described below is applicable to structures of the present invention other than the first example embodiment.

The stress of the silicon nitride film 4 is preferably about −300 MPa or greater and about 50 MPa or smaller, for example. The acoustic wave device 10 is obtained by, for example, dividing a wafer on which a plurality of acoustic wave elements are formed. The wafer is divided into the plurality of piezoelectric substrates 2. Accordingly, the wafer used to manufacture the acoustic wave device 10 includes the silicon nitride film 4, similarly to the piezoelectric substrate 2. When the stress of the silicon nitride film 4 falls within the range described above, the wafer can be prevented from warping. Accordingly, in the manufacturing process of the acoustic wave device 10, the wafer can be suitably transported, and the productivity can be enhanced.

In addition, when the stress of the silicon nitride film 4 is about −300 MPa or greater and about 50 MPa or smaller, for example, the stress can be easily controlled over the entire acoustic wave device 10.

The thickness of the silicon nitride film 4 is preferably about 30 nm or greater and about 250 nm or smaller, for example. As a result, the stress of the silicon nitride film 4 can be, for example, about −300 MPa or greater and about 50 MPa or smaller with greater certainty. The thickness of the silicon nitride film 4 is more preferably about 50 nm or greater and about 250 nm or smaller, even more preferably about 50 nm or greater and about 200 nm or smaller. In this case, the productivity can be enhanced with greater certainty. In addition, the stress can be more easily controlled over the entire acoustic wave device 10.

In addition, since the strength of the silicon nitride film 4 itself is high, when the thickness of the silicon nitride film 4 falls within the range described above, even if the profile of the acoustic wave device 10 is made low, the strength of the acoustic wave device 10 can be maintained sufficiently high by reducing the thickness of the support substrate 3 or the thicknesses of components other than the support substrate 3. It should be noted that the Si/N composition ratio in the silicon nitride film 4 is desirably about 0.95 or greater, for example. In this case, the control of the film thickness and the stress becomes easier. Here, the Si/N composition ratio refers to the composition ratio of elements, specifically the ratio of Si to N.

In the first example embodiment and the second example embodiment, when the thickness of the portion of the piezoelectric layer 6 in which the IDT electrode 7 is provided is d, and the distance between the centers of adjacent electrode fingers is p, d/p is about 0.5 or smaller, for example. It should be noted that d/p is preferably about 0.24 or smaller, for example. As a result, a bulk wave in the thickness shear mode can be excited more suitably, and the value of the fractional bandwidth of the acoustic wave resonators can be sufficiently increased. The fractional bandwidth is represented by (|fa−fr|/fr)×100(%) where the resonant frequency is fr and the anti-resonant frequency is fa.

FIG. 8 is a diagram illustrating the relationship between d/p and the fractional bandwidth of the acoustic wave resonator.

As is clear from FIG. 8, when d/p>about 0.5 is satisfied, the fractional bandwidth is smaller than about 5%, for example. In contrast, when d/p≤about 0.5 is satisfied, the fractional bandwidth can be about 5% or greater, for example. Accordingly, the electromechanical coupling coefficient of a bulk wave in the thickness shear mode can be increased. When d/p≤about 0.24 is satisfied, the fractional bandwidth can be about 7% or greater, for example. Accordingly, the electromechanical coupling coefficient of a bulk wave in the thickness shear mode can be effectively increased.

When the metallization ratio of the electrode fingers with respect to the excitation regions C is MR, MR≤about 1.75(d/p)+0.075 preferably is satisfied, for example. In this case, since the value of the fractional bandwidth of the acoustic wave resonator is not too large, spurious emission between the resonant frequency and the anti-resonant frequency can be suppressed from occurring. Details of this will be described below.

It should be noted that, in this specification, the metallization ratio MR of the electrode fingers with respect to the excitation regions C is the proportion of the portion of the piezoelectric layer 6 covered with the metal of the electrode fingers to the excitation regions C in plan view. Specifically, the ratio of the area of the first electrode fingers 18 and the second electrode fingers 19 in the excitation regions C to the area of the excitation regions C in plan view is referred to as the metallization ratio MR. It should be noted that, when the width of the electrode fingers located in the excitation regions C is constant, the metallization ratio MR can also be calculated by the total width of the electrode fingers located in the excitation regions C being divided by the dimension of the excitation regions C in the electrode finger orthogonal direction. It should be noted that the width of the electrode fingers is the dimension of the electrode fingers in the electrode finger orthogonal direction.

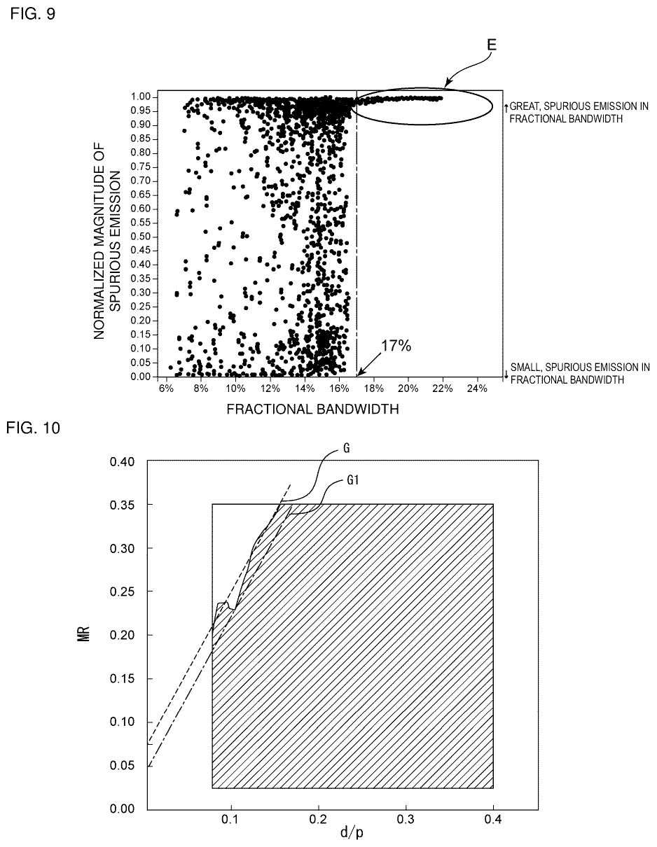

FIG. 9 is a diagram illustrating the relationship between the fractional bandwidth of the acoustic wave resonator and the normalized magnitude of spurious emission. FIG. 9 illustrates the phase rotation amount of spurious emission measured each time the fractional bandwidth was changed by the thickness of the piezoelectric layer and the dimension of the electrode fingers being changed. It should be noted that the normalized magnitude of spurious emission in FIG. 9 is specifically the value obtained by the phase rotation amount of the impedance of spurious emission being normalized by 180°, for example. The results illustrated in FIG. 9 have been obtained by use of the piezoelectric layer made of Z-cut LiNbO₃, but a similar trend is observed when the piezoelectric layer with another cut-angle is used.

In the region surrounded by ellipse E in FIG. 9, the normalized magnitude of spurious emission between the resonant frequency and the anti-resonant frequency is about 1.0, for example. When the fractional bandwidth of the acoustic wave resonator exceeds about 17%, the normalized magnitude of spurious emission can become about 1.0 or greater, for example. Accordingly, the fractional bandwidth is preferably about 17% or smaller, for example. As a result, spurious emission between the resonant frequency and the anti-resonant frequency can be reduced or prevented.

FIG. 10 is a diagram illustrating the relationship between d/p, the metallization ratio MR, and the fractional bandwidth. FIG. 10 illustrates the fractional bandwidth calculated each time the d/p and the metallization ratio MR were changed.

The hatched portion in FIG. 10 is the region in which the fractional bandwidth is about 17% or smaller, for example. The boundary between the hatched region and the non-hatched region is approximately represented by a dashed line G. The dashed line G is represented by MR=about 1.75(d/p)+0.075, for example. In addition, MR≤about 1.75(d/p)+0.075 preferably is satisfied, for example. In this case, the fractional bandwidth can be easily set to about 17% or smaller, for example.

On the one hand, a dot-dash line G1 in FIG. 10 indicates the boundary at which the slope of the change in the metallization ratio MR with respect to the change in d/p is the same as the slope of the dashed line G and the fractional bandwidth is about 17% or smaller across the entire range, for example. The dot-dash line G1 is represented by MR=about 1.75(d/p)+0.05, for example. In addition, MR≤about 1.75(d/p)+0.05 preferably is satisfied, for example. In this case, the fractional bandwidth can be about 17% or smaller with greater certainty, for example.

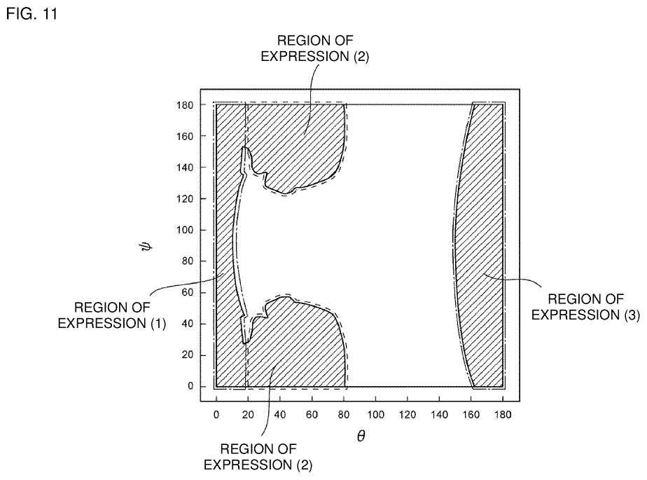

FIG. 11 is a diagram illustrating the map of the fractional bandwidth with respect to the Euler angles (0°, θ, ψ) of LiNbO₃ when d/p approaches 0 as closely as possible. The hatched portions in FIG. 11 are regions in which a fractional bandwidth of 5% or greater is obtained, and the ranges of these regions are approximated as the ranges represented by expressions (1), (2), and (3) below.

$$( 0 ° \pm 10 ° , 0 ° to 20 ° , any ψ ) \qquad Expression ( 1 )$$

$$( 0 ° \pm 10 ° , 20 ° to 80 ° , 0 ° to 60 {° ( 1 - {( 0 - 50 )}^{2} / 900 )}^{1 / 2} ) or ( 0 ° \pm 10 ° , 20 ° to 80 ° , [ 180 ° - 60 {° ( 1 - {( 0 - 50 )}^{2} / 900 )}^{1 / 2} ] to 180 ° ) \qquad Expression ( 2 )$$

$$( 0 ° \pm 10 ° , [ 180 ° - 30 {° ( 1 - {( ψ - 90 )}^{2} / 8100 )}^{1 / 2} ] to 180 ° , any ψ ) \qquad Expression ( 3 )$$

The Euler angles (φ, θ, ψ) of the lithium niobate of the piezoelectric layer 6 preferably fall within the range indicated by the expression (1), (2), or (3). As a result, the fractional bandwidth of the acoustic wave resonator can be sufficiently widened. This is also true when the piezoelectric layer 6 is made of lithium tantalate.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a support substrate;
an intermediate layer on the support substrate;
a piezoelectric layer on the intermediate layer; and
an IDT electrode on the piezoelectric layer and including a plurality of electrode fingers; wherein
d/p is about 0.5 or smaller where a thickness of a portion of the piezoelectric layer in which the IDT electrode is provided is d, and a distance between centers of adjacent electrode fingers of the plurality of electrode fingers is p, a cavity is between the piezoelectric layer and the support substrate and overlaps with the IDT electrode in plan view;
the acoustic wave device further comprising:
one of a silicon nitride film, an amorphous silicon film, or a polycrystalline silicon film each including at least a portion provided between the support substrate and the intermediate layer and each facing the piezoelectric layer with at least one of the cavity and the intermediate layer therebetween.

2. The acoustic wave device according to claim 1, wherein the acoustic wave device includes the silicon nitride film, and a thickness of the silicon nitride film is about 30 nm or greater and about 250 nm or smaller.

3. The acoustic wave device according to claim 1, wherein the acoustic wave device includes the silicon nitride film, and a stress of the silicon nitride film is about −300 MPa or greater and about 50 MPa or smaller.

4. The acoustic wave device according to claim 1, wherein the intermediate layer is a silicon oxide layer.

5. The acoustic wave device according to claim 1, wherein the support substrate is a silicon substrate.

6. The acoustic wave device according to claim 1, wherein d/p is about 0.24 or smaller.

7. The acoustic wave device according to claim 1, wherein, when a direction orthogonal to a direction in which the plurality of electrode fingers extend is an electrode finger orthogonal direction, and a region, between the centers of adjacent electrode fingers of the plurality of electrode fingers, in which the adjacent electrode fingers overlap with each other in the electrode finger orthogonal direction is an excitation region, MR ≤about 1.75(d/p)+0.075 is satisfied where a metallization ratio of the electrode fingers with respect to the excitation region is MR.

8. The acoustic wave device according to claim 1, wherein, when a direction orthogonal to a direction in which the plurality of electrode fingers extend is an electrode finger orthogonal direction, and a region, between the centers of adjacent electrode fingers of the plurality of electrode fingers, in which the adjacent electrode fingers overlap with each other in the electrode finger orthogonal direction is an excitation region, MR ≤about 1.75(d/p)+0.050 is satisfied where a metallization ratio of the electrode fingers with respect to the excitation region is MR.

9. The acoustic wave device according to claim 1, wherein
the piezoelectric layer includes lithium niobate or lithium tantalate, and Euler angles (φ, θ, ψ) of the lithium niobate or the lithium tantalate of the piezoelectric layer fall within a range defined by expression (1), (2), or (3):
$$( 0 ° \pm 10 ° , 0 ° to 20 ° , any ψ ) \qquad Expression ( 1 )$$
$$( 0 ° \pm 10 ° , 20 ° to 80 ° , 0 ° to 60 {° ( 1 - {( 0 - 50 )}^{2} / 900 )}^{1 / 2} ) or ( 0 ° \pm 10 ° , 20 ° to 80 ° , [ 180 ° - 60 {° ( 1 - {( 0 - 50 )}^{2} / 900 )}^{1 / 2} ] to 180 ° ) \qquad Expression ( 2 )$$
$$( 0 ° \pm 10 ° , [ 180 ° - 30 {° ( 1 - {( ψ - 90 )}^{2} / 8100 )}^{1 / 2} ] to 180 ° , any ψ ) . \qquad Expression ( 3 )$$

10. The acoustic wave device according to claim 1, wherein the cavity includes a recess in the intermediate layer or a through hole in the intermediate layer.

11. The acoustic wave device according to claim 1, wherein the acoustic wave device generates a bulk wave in a thickness shear mode.

12. The acoustic wave device according to claim 1, further comprising a dielectric film on the IDT electrode.

13. The acoustic wave device according to claim 12, wherein a through hole is provided in the dielectric film.

14. The acoustic wave device according to claim 12, wherein a through hole is provided in a portion of the piezoelectric layer and the dielectric film so as to reach the cavity.

15. The acoustic wave device according to claim 1, wherein a through hole is provided in a portion of the intermediate layer between the cavity and the piezoelectric layer.

16. The acoustic wave device according to claim 1, wherein a through hole is provided in the piezoelectric layer.

17. The acoustic wave device according to claim 1, wherein the acoustic wave device is a two port acoustic wave resonator.

18. The acoustic wave device according to claim 1, wherein the acoustic wave device includes the silicon nitride film, and a thickness of the silicon nitride film is about 50 nm or greater and about 250 nm or smaller.

19. The acoustic wave device according to claim 1, wherein the acoustic wave device includes the silicon nitride film, and a thickness of the silicon nitride film is about 50 nm or greater and about 200 nm or smaller.

20. The acoustic wave device according to claim 1, wherein the acoustic wave device includes the silicon nitride film with a Si to N composition ratio of about 0.95 or greater.
